(19) United States
(12) Patent Application Publication
(10) Pub. No.: US 2005/0285677 A1
(43) Pub. Date: Dec. 29, 2005

(54) Fully balanced transconductor

(76) Inventor: Matthew David Rowley, Austin, TX (US)

Correspondence Address: TEXAS INSTRUMENTS INCORPORATED, P O BOX 655474, M/S 3999, DALLAS, TX, 75265, US

(21) Appl. No.: 11/047,195

(22) Filed: Jan. 31, 2005

Related U.S. Application Data
(60) Provisional application No. 60/583,796, filed on Jun. 28, 2004.

(51) Int. Cl. H03F 3/45

(52) U.S. Cl. 330/259

(57) ABSTRACT

A fully balanced transconductor circuit, such as by utilizing two 5 transistor tranconductors in a single circuit sharing the common mode node and operating them 180 degrees out of phase, to realize a current source in saturation under all conditions. The present invention may be utilized in a low power circuit with good jitter performance and large output swings.

### PRIORITY CLAIM

This application claims priority of U.S. Provisional application Ser. No. 60/583,796 entitled “Fully Balanced, Large Swing Transconductor” filed Jun. 28, 2004, the teaching of which are incorporated herein by reference.

### FIELD OF THE INVENTION

The present invention is generally related to hard disk drive amplifiers, and more specifically to transconductors operable therein.

### BACKGROUND OF THE INVENTION

In data communication or linear applications, it is crucial to develop circuits with high bandwidth and low jitter. Additionally, having an amplifier with variable gain allows for circuit topologies which can handle large input dynamic ranges without performance degradation. To this end, fully differential circuits are well known for realizing low jitter circuits due to their inherent common-mode rejection and supply rejection characteristics.

### SUMMARY OF THE INVENTION

The present invention achieves technical advantages as a fully balanced transconductor circuit. In one embodiment of the invention, a fully balanced transconductor is realized utilizing two 5 transistor tranconductors in a single circuit sharing a common mode node and operable 180 degrees out of phase, such as to realize a current source in saturation under all conditions. The present invention may be utilized in a low power circuit with good jitter performance and large output swings.

### BRIEF DESCRIPTION OF THE DRAWINGS

FIG. 1 is a schematic of a fully balanced differential circuit according to one embodiment of the present invention; and

FIG. 2 is a waveform diagram of signals at various nodes of the circuit of FIG. 1.

### DETAILED DESCRIPTION OF THE PREFERRED EMBODIMENT

Standard five transistor transconductor circuits have been used as differential to single ended converters (CML to CMOS converters), but due to their inherent imbalances the jitter performance suffers since the current source will usually be pulled in and out of saturation. These transconductors are very simple, well understood, small, and low-power though so it is preferable to try and use these circuits.

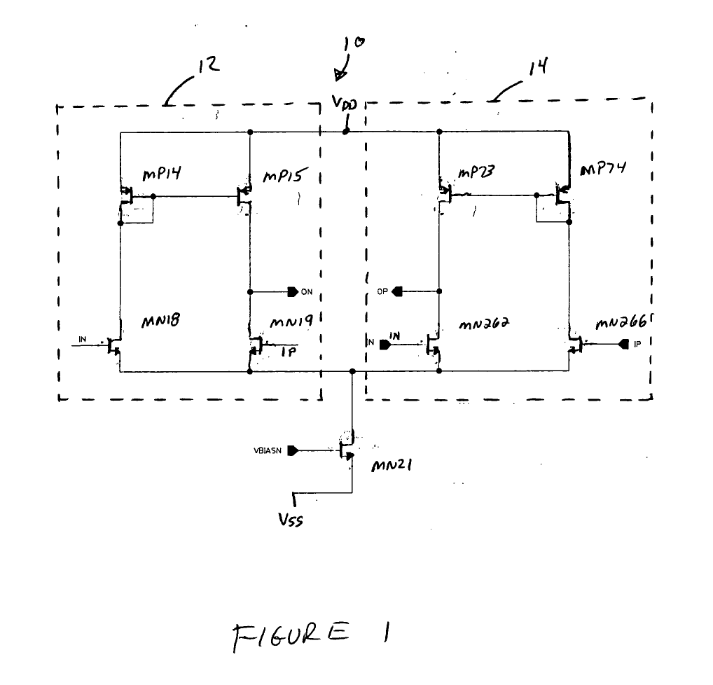

Referring to FIG. 1, there is shown a circuit 10 according to a first embodiment of the invention. Circuit 10 can be functionally viewed as two 5 transistor transconductors each labeled at 12 and 14, each transconductor sharing a common bias current source provided by transistor MN21. The first transconductor 12 is composed of transistors MN18, MN19, MP14, and MP15, while the second transconductor 14 is composed of transistors MN262, MN266, MP73, and MP74. These two transconductor circuits 12 and 14 are operated 180 degrees out of phase to advantageously form a balanced, fully-differential, high gain, large output swing amplifier 10.

Transistor MN21 sets a fixed bias current for the circuit 10. The amount of current is user selectable, and is controlled through the gate connection to transistor MN21 denoted as ‘VBIASN’ in FIG. 1. The drain of transistor MN21 forms the common mode node needed for proper differential functionality of the two circuits 12 and 14.

Two differential pairs are formed by transistor pairs MN18/MN19 and MN262/MN266, respectively. Current mirror pairs are formed by transistor pairs MP14/MP15 and MP73/MP74, respectively.

Circuit operation is as follows. The logic value of output node OP follows IP and node ON follows input node IN. When node IP is ‘high’ and node IN is ‘low’, the bias current provided by the current source MN21 flows in transistors MN266/MP74 and MN19. No current is flowing in transistors MN18/MP14 and MN262. The result is that the current flowing through transistor MP74 is mirrored to transistor MP73. Since node IN is ‘low’, no current is flowing in transistor MN262, therefore, current flows through transistor MP73 long enough to pull output node OP ‘high’ or to VDD. Similarly, no current is flowing in transistors MN18/MP14 since input node IN is ‘low’, therefore, current flows through transistor MP19 long enough to pull node ON ‘low’ or to the common mode node voltage. For this circuit, ‘low’ is defined as the voltage on the common mode node defined by the drain of transistor MN21, and the sources of transistors MN18/MN19/MN262/MN266.

After the circuit 10 stabilizes, all the bias current sourced by transistor MN21 is flowing through the leg containing transistors MN266/MP74. Advantageously, this function keeps the bias current flowing properly through the current source.

When node IP switches to ‘low’ and thus node IN switches to ‘high’, the bias current begins to flow through transistors MN18/MP14 and MN262. Current is being shut off in transistors MN19 and MN266/MP74. Therefore, the current in transistor MP14 is being mirrored to that in transistor MP15. This pulls output node ON ‘high’. Similarly, the current through transistor MP73 is cut off so that the current flows through transistor MN262 long enough to pull node OP ‘low’ or to the common mode node voltage.

After the circuit 10 stabilizes, all the bias current sourced by transistor MN21 is flowing through the leg containing transistors MN18/MP14. This function keeps the current flowing properly through the current source.

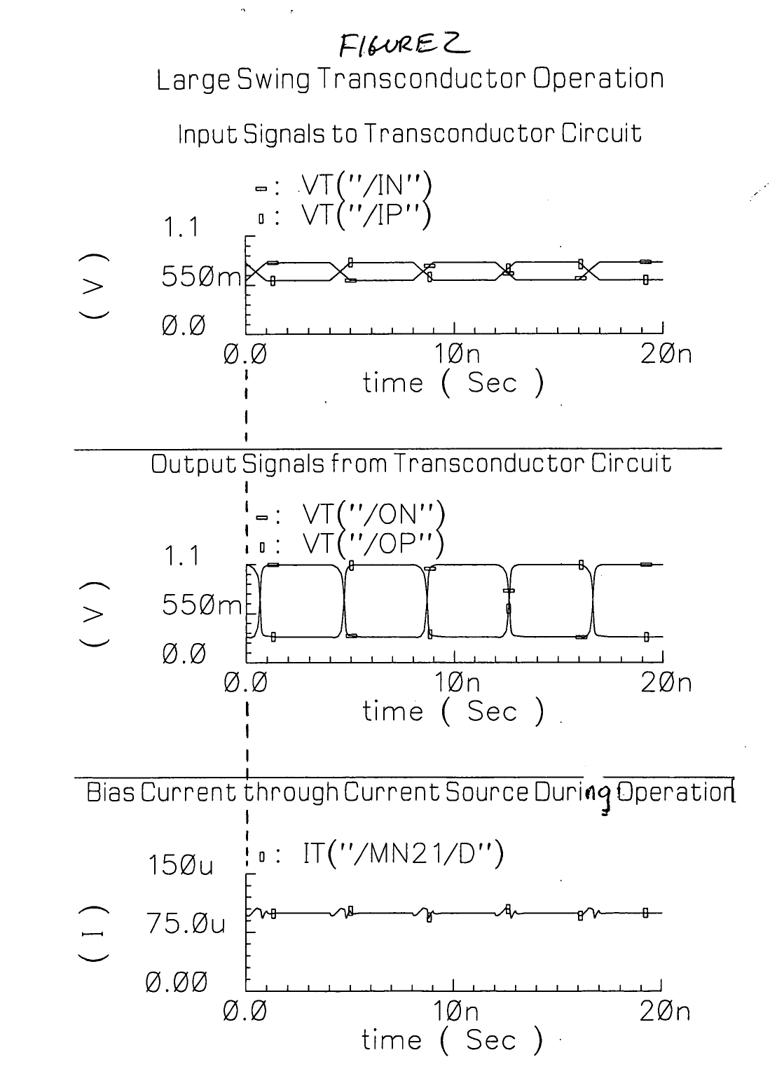

Referring now to FIG. 2, there is shown at 20 waveforms of various nodes of circuit 10, depicting the bias current of transistor MN21 in saturation at all times, and circuit 10 operating as a fully differential circuit with low jitter.

The problems solved by this circuit are:

Keeps the current flowing through the current source without interruption. This increases the bandwidth and improves jitter performance. This circuit remains in fully differential operation to take advantage of common mode rejection and power supply rejection. Finally, large output swings are maintained while achieving the above, from Vcommon mode to VDD.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

1. A circuit, comprising:
at least one transconductor circuit having a plurality of transistors and a bias current source, wherein the bias current source operates in saturation for all operating conditions, the circuit providing a balanced, fully-differential output signal.

2. The circuit as specified in claim 1 comprising at least two of the transconductor circuits.

3. The circuit as specified in claim 2 wherein the transconductor circuits operate 180 degrees out of phase with respect to each other.

4. The circuit as specified in claim 2 wherein the transconductor circuits commonly share the bias current source.

5. The circuit as specified in claim 2 wherein the transconductor circuits share a common node.

6. The circuit as specified in claim 2 wherein the bias current source is selectable.

7. The circuit as specified in claim 6 wherein the current source is selectable through a gate connection of a FET transistor.

8. The circuit as specified in claim 7 wherein a drain of the FET forms a common mode node of the two transconductor circuits.

9. The circuit as specified in claim 2 wherein the two transconductor circuits each comprise a standard 5 transistor transconductor circuit.

10. The circuit as specified in claim 1 wherein the current source continuously conducts current even during a signal transition of the fully differential output signal.
